(19) United States
(12) Patent Application Publication
(10) Pub. No.: US 2023/0221350 A1
(43) Pub. Date: Jul. 13, 2023

(54) INSPECTION DEVICE

(71) Applicant: YOKOWO CO., LTD., Kita-ku, Tokyo (JP)

(72) Inventor: Tomohisa HOSHINO, Tomioka-shi, Gunma (JP)

(73) Assignee: YOKOWO CO., LTD., Kita-ku, Tokyo (JP)

(21) Appl. No.: 18/009,993

(22) PCT Filed: Jun. 11, 2021
(86) PCT No.: PCT/JP2021/022238

§ 371 Date: Dec. 13, 2022

(30) Foreign Application Priority Data
Jun. 22, 2020 (JP) 2020-106765

(51) Int. Cl. G01R 1/067; G01R 1/04

(52) U.S. Cl. CPC G01R 1/06722; G01R 1/0433

(57) ABSTRACT

An inspection device comprising: a first elastomer defining a hole; and a plunger overlapping with the first elastomer, wherein a conductive film is formed over an inner wall of the hole, and the plunger is electrically connected to the conductive film.

### TECHNICAL FIELD

The present invention relates to an inspection device.

### BACKGROUND ART

Various inspection devices have been developed for inspecting characteristics of electronic devices such as integrated circuits (ICs). As disclosed in Patent Document 1, an inspection device includes a socket and a probe inserted into the socket. The probe includes a plunger biased by a spring.

### RELATED DOCUMENT

### Patent Document

Patent Document 1: Japanese Unexamined Patent Publication No. 2017-76587

### SUMMARY OF THE INVENTION

### Technical Problem

Various requests such as a request for an inspection in a high frequency band request a short free length of the probe in some case. For example, when the plunger is biased by the spring as disclosed in Patent Document 1, a stroke having a sufficient length may not be achieved with a short free length of the probe.

One example of an object of the present invention is to shorten the free length of the probe while achieving the stroke having a sufficient length. Other object of the present invention will be apparent from the description of the present specification.

### Solution to Problem

An aspect of the present invention is an inspection device including a first elastomer defining a hole, and a plunger overlapping with the first elastomer, in which a conductive film is formed over an inner wall of the hole, and the plunger is electrically connected to the conductive film.

### Advantageous Effects of Invention

According to the above aspect of the present invention, it is possible to shorten the free length of the probe while achieving the stroke having a sufficient length.

### BRIEF DESCRIPTION OF THE DRAWINGS

FIG. 1 is a plan view of an inspection device according to Embodiment 1.

FIG. 2 is a cross-sectional view taken along line A-A′ of FIG. 1.

FIG. 3 is a perspective cross-sectional view showing the details of the inspection device according to Embodiment 1.

FIG. 4 is a view for describing an example of a method of manufacturing the inspection device according to Embodiment 1.

FIG. 5 is a perspective cross-sectional view of an inspection device according to a modification example.

FIG. 6 is a perspective cross-sectional view of an inspection device according to Embodiment 2.

### DESCRIPTION OF EMBODIMENTS

In the following, embodiments of the present invention will be described with reference to the drawings. It should be noted that, in all drawings, similar components are designated by the same reference numerals, and the description thereof will not be repeated.

In the present specification, ordinal numbers, such as “first”, “second”, and “third”, are merely used to distinguish similarly named configurations unless otherwise noted, and do not imply any particular feature of the configuration, such as order or importance.

### Embodiment 1

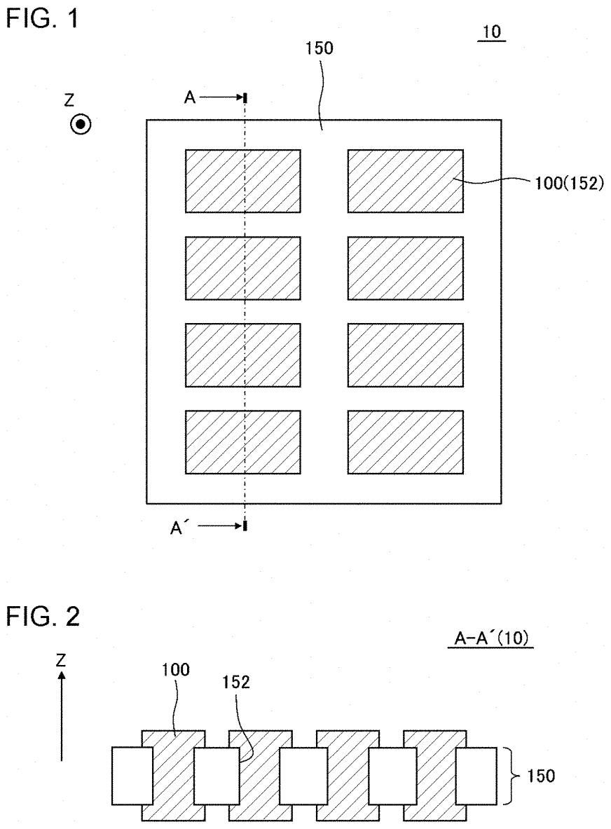

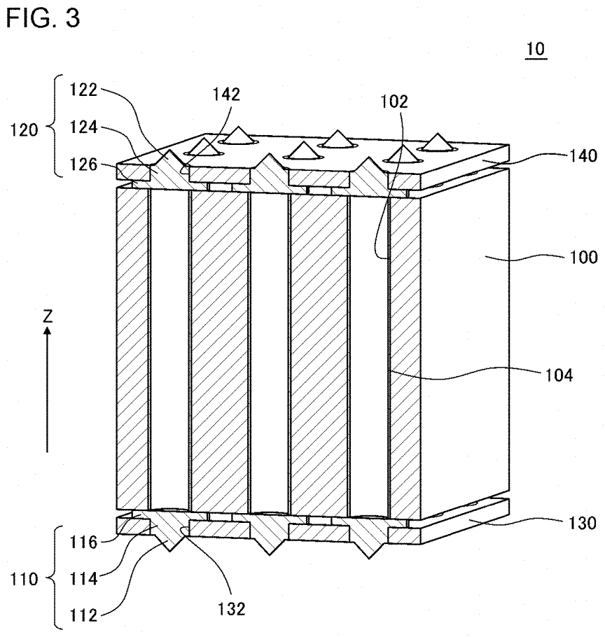

FIG. 1 is a plan view of an inspection device 10 according to Embodiment 1. FIG. 2 is a cross-sectional view taken along line A-A′ of FIG. 1. FIG. 3 is a perspective cross-sectional view showing the details of the inspection device 10 according to Embodiment 1.

In FIG. 1, a white circle with a black dot indicating a vertical direction Z means that a direction from the back to the front of the paper surface is an upward direction of the vertical direction Z, and a direction from the front to the back of the paper surface is a downward direction of the vertical direction Z. In FIGS. 2 and 3, a direction indicated by an arrow indicating the vertical direction Z is the upward direction of the vertical direction Z. A direction opposite to the direction indicated by the arrow indicating the vertical direction Z is the downward direction of the vertical direction Z.

As shown in FIGS. 1 and 2, the inspection device 10 includes a plurality of first elastomers 100 and a frame 150. As shown in FIG. 3, the inspection device 10 further includes a plurality of first plungers 110, a plurality of second plungers 120, a first pin plate 130, and a second pin plate 140. Each first plunger 110 includes a first tip contactor 112, a first columnar part 114, and a first receiving part 116. Each second plunger 120 includes a second tip contactor 122, a second columnar part 124, and a second receiving part 126. At least a portion of the first elastomer 100 such as a periphery of a hole 102 described later in the first elastomer 100, a conductive film 104 described later, each first plunger 110, and each second plunger 120 function as a probe. Each first plunger 110 and each second plunger 120 are biased in the vertical direction Z by at least a portion of the first elastomer 100 such as the periphery of the hole 102. It should be noted that FIGS. 1 and 2 do not show the hole 102, the conductive film 104, the first plungers 110, the second plungers 120, the first pin plate 130 and the second pin plate 140 shown in FIG. 3.

First, the plurality of first elastomers 100 and the frame 150 will be described with reference to FIGS. 1 and 2.

The frame 150 is, for example, made of metal. The frame 150 defines a plurality of openings 152 disposed in a grid. Each of the plurality of first elastomers 100 is provided in each of the plurality of openings 152. As a result, each first elastomer 100 is supported by an inner edge of the opening 152. The first plunger 110 is located below the first elastomer in the vertical direction Z and can be biased downward in the vertical direction Z. In this case, for example, even if force is applied to the first plunger 110 in a depth direction of the opening 152, that is, in the vertical direction Z when the inspection device 10 performs an inspection, spreading of each first elastomer 100 in a planar direction, that is, in a direction perpendicular to the vertical direction Z can be suppressed as compared with a case in which each first elastomer 100 is not supported by the inner edge of the opening 152. However, the inspection device 10 may not include the frame 150.

Each first elastomer 100 has a sheet shape. In one example, the first elastomer 100 is made of a polymeric material having elasticity, for example a polymeric material such as silicone, polyimide, or styrene-butadiene rubber (SBR).

As shown in FIG. 2, the first elastomer 100 includes a portion embedded in the opening 152 of the frame 150 (a portion located in the opening 152), a portion exposed from an upper opened end of the opening 152 of the frame 150, and a portion exposed from a lower opening end of the opening 152 of the frame 150. A width of the portion of the first elastomer 100 exposed from the upper opening end of the opening 152 in a left-right direction in the drawing is wider than a width of the upper opening end of the opening 152 in the left-right direction in the drawing. Accordingly, the portion of the first elastomer 100 exposed from the upper opening end of the opening 152 can be suppressed from exiting downward the frame 150 through the opening 152. A width of the portion of the first elastomer 100 exposed from the lower opening end of the opening 152 in a left-right direction in the drawing is wider than a width of the lower opening end of the opening 152 in the left-right direction in the drawing. Accordingly, the portion of the first elastomer 100 exposed from the lower opening end of the opening 152 can be suppressed from exiting upward the frame 150 through the opening 152. It should be noted that the first elastomer 100 may not include the portion exposed from the upper opened end of the opening 152 of the frame 150 and the portion exposed from the lower opening end of the opening 152 of the frame 150. Alternatively, the first elastomer 100 may include only one of the portion exposed from the upper opened end of the opening 152 of the frame 150 and the portion exposed from the lower opening end of the opening 152 of the frame 150. The width of the portion of the first elastomer 100 exposed from the opening end of the opening 152 in the left-right direction in the drawing may be equal to or less than the width of the opening end of the opening 152 in the left-right direction in the drawing.

Next, the details of each first elastomer 100 will be described with reference to FIG. 3.

The first elastomer 100 defines a plurality of holes 102 that penetrate the first elastomer 100 along the vertical direction Z.

The conductive film 104 is formed on an inner wall of each hole 102. In one example, the conductive film 104 includes metal such as at least one selected from the group consisting of nickel, copper, and gold. The conductive film 104 is, for example, a multilayer film of these metals.

Each hole 102 is hollow. In this case, as compared with a case in which the conductive film 104 is formed on the inner wall of the hole 102 and the hole 102 is solid (the hole 102 is filled), a material and a process for making the hole 102 solid are unnecessary, and a manufacturing cost of the inspection device 10 can be reduced.

The first plunger 110 is located below the first elastomer 100. The first plunger 110 overlaps with the first elastomer 100 in the vertical direction Z. Specifically, the first plunger 110 overlaps with the hole 102 in the vertical direction Z. Accordingly, the first plunger 110 can be biased in a direction away from the second plunger 120, that is, downward by the first elastomer 100. The first plunger 110 is electrically connected to the conductive film 104. Accordingly, the first plunger 110 can be electrically connected to the second plunger 120 through the conductive film 104. If the first plunger 110 does not overlap with the hole 102 in the vertical direction Z, an electrical path such as a conductive material embedded in the first elastomer 100 needs to be provided separately from the conductive film 104 in order to electrically connect the first plunger 110 to the conductive film 104. When the first plunger 110 overlaps with the hole 102 in the vertical direction Z, however, the first plunger 110 can be directly connected to the conductive film 104 without through the electrical path such as the conductive material embedded in the first elastomer 100. Accordingly, as compared with a case in which the electrical path is provided, a material and a process for manufacturing the electrical path itself are unnecessary, and the manufacturing cost of the inspection device 10 can be reduced. It should be noted that the first plunger 110 may be offset from the hole 102 in a direction orthogonal to the vertical direction Z. Even in this case, the first plunger 110 can be connected to the conductive film 104 through the electrical path such as the conductive material embedded in the first elastomer 100.

The first tip contactor 112 includes metal such as at least one selected from the group consisting of rhodium, ruthenium, iridium, tungsten, and tantalum.

A width of the first tip contactor 112 is narrowed from a base end to a tip of the first tip contactor 112. The first tip contactor 112 is a conic solid such as a cone or a pyramid, and has a tapered shape from the base end to the tip of the first tip contactor 112. A tip of the first tip contactor 112 has a flat surface of, for example, equal to or more than 1 μm and equal to or less than 20 μm. However, the shape of the tip of the first tip contactor 112 is not limited to this example.

The first columnar part 114 includes metal such as at least one selected from the group consisting of copper and nickel.

The first columnar part 114 is connected to the base end of the first tip contactor 112. The first tip contactor 112 and the first columnar part 114 may be integrated or separate. A height of the first columnar part 114 is, for example, equal to or more than 5 μm and equal to or less than 300 μm. The first columnar part 114 is a column such as a cylinder or a prism. When the first columnar part 114 is a cylinder, a diameter of the first columnar part 114 is, for example, equal to or more than 20 μm and equal to or less than 500 μm. However, the shape of the first columnar part 114 is not limited to this example.

The first receiving part 116 includes metal such as at least one selected from the group consisting of copper and nickel.

The first receiving part 116 is connected to an end portion of the first columnar part 114 opposite to the first tip contactor 112. The first columnar part 114 and the first receiving part 116 may be integrated or separated. The first receiving part 116 has a width wider than a width of the first columnar part 114. A thickness of the first receiving part 116 is, for example, equal to or more than 5 μm and equal to or less than 200 μm. An upper surface of the first receiving part 116 is flat. However, at least one convex part may be formed on the upper surface of the first receiving part 116.

The first pin plate 130 is made of, for example, polyimide, liquid crystal polymer, or glass substrate.

The first pin plate 130 defines a plurality of first through-holes 132. Each of the plurality of first plungers 110 is inserted into each of the plurality of first through-holes 132. The plurality of first plungers 110 can be arranged at a minute pitch (narrow pitch) of, for example, equal to or more than 10 μm and equal to or less than 500 μm.

At least a portion of the first tip contactor 112 is exposed from a lower end of the first through-hole 132 of the first pin plate 130. At least a portion of the first columnar part 114 penetrates the first through-hole 132. The first receiving part 116 is located between an upper surface of the first pin plate 130 and a lower surface of the first elastomer 100. The width of the first receiving part 116 in the left-right direction in the drawing is wider than a width of the first through-hole 132 in the left-right direction in the drawing. Accordingly, the first receiving part 116 is caught by a peripheral portion of an opening end of the first through-hole 132 on the upper surface of the first pin plate 130. In this case, even if the first plunger 110 is biased downward by the first elastomer 100, the first receiving part 116 can be suppressed from exiting downward the first pin plate 130 through the first through-hole 132. Thus, as compared with a case in which the first receiving part 116 is not provided, even if a length of the first plunger 110 (a length of the first columnar part 114) is shortened, the first plunger 110 is unlikely to exit below the first pin plate 130. The length of the first plunger 110 can be shortened, and the first plunger 110 can be applied to an inspection in a high frequency band of equal to or more than 1 GHz and equal to or less than 100 GHz.

The second plunger 120 is located above the first elastomer 100. The second plunger 120 overlaps with the first elastomer 100 in the vertical direction Z. Specifically, the second plunger 120 overlaps with the hole 102 in the vertical direction Z. Accordingly, the second plunger 120 can be biased in a direction away from the first plunger 110, that is, upward by the first elastomer 100. The second plunger 120 is electrically connected to the conductive film 104. Accordingly, the second plunger 120 can be electrically connected to the first plunger 110 through the conductive film 104. If the second plunger 120 does not overlap with the hole 102 in the vertical direction Z, an electrical path such as a conductive material embedded in the first elastomer 100 needs to be provided separately from the conductive film 104 in order to electrically connect the second plunger 120 to the conductive film 104. When the second plunger 120 overlaps with the hole 102 in the vertical direction Z, however, the second plunger 120 can be directly connected to the conductive film 104 without through the electrical path such as the conductive material embedded in the first elastomer 100. Accordingly, as compared with a case in which the electrical path is provided, the material and the process for manufacturing the electrical path itself are unnecessary, and the manufacturing cost of the inspection device 10 can be reduced. It should be noted that the second plunger 120 may be offset from the hole 102 in a direction orthogonal to the vertical direction Z. Even in this case, the second plunger 120 can be connected to the conductive film 104 through the electrical path such as the conductive material embedded in the first elastomer 100.

The second pin plate 140 defines a plurality of second through-holes 142. Each of the plurality of second plungers 120 is inserted into each of the plurality of second through-holes 142 in the same manner as the plurality of first plungers 110 and the first pin plate 130.

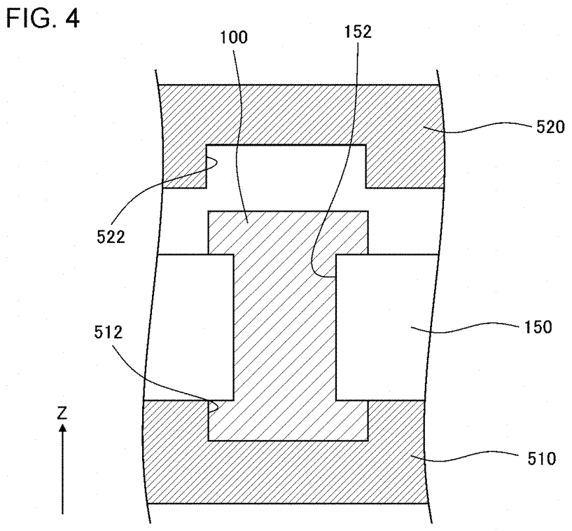

FIG. 4 is a view for describing an example of a method of manufacturing the inspection device 10 according to Embodiment 1. The inspection device 10 is manufactured as follows.

First, the frame 150 is installed on a lower die 510. Specifically, a first recess part 512 is formed on an upper surface of the lower die 510. The frame 150 is disposed such that the lower opening end of the opening 152 of the frame 150 overlaps with the first recess part 512 of the lower die 510. A width of the first recess part 512 of the lower die 510 in the left-right direction in the drawing is wider than the width of the lower opening end of the opening 152 of the frame 150 in the left-right direction in the drawing. Thus, a width of a portion of the first elastomer 100 molded by the first recess part 512 of the lower die 510 in the left-right direction in the drawing is wider than the width of the portion of the first elastomer 100 embedded in the opening 152 in the left-right direction in the drawing.

Next, the opening 152 of the frame 150 and the first recess part 512 of the lower die 510 are filled with the first elastomer 100 such that a part of the first elastomer 100 protrudes from an upper end of the opening 152 of the frame 150.

Next, the upper die 520 is installed on the first elastomer 100. Specifically, a second recess part 522 is formed on a lower surface of the upper die 520. The frame 150 is disposed such that the upper opening end of the opening 152 of the frame 150 overlaps with the second recess part 522 of the upper die 520. A width of the second recess part 522 of the upper die 520 in the left-right direction in the drawing is wider than the width of the upper opening end of the opening 152 of the frame 150 in the left-right direction in the drawing. Thus, a width of a portion of the first elastomer 100 molded by the second recess part 522 of the upper die 520 in the left-right direction in the drawing is wider than the width of the portion of the first elastomer 100 embedded in the opening 152 in the left-right direction in the drawing.

Next, the first elastomer 100 is sandwiched between the lower die 510 and the upper die 520. Next, the first elastomer 100 is thermally cured. As a result, the first elastomer 100 is formed.

Next, the first elastomer 100 and the frame 150 are removed from the lower die 510 and the upper die 520.

Next, the plurality of holes 102 are formed in the first elastomer 100. Each hole 102 is formed by, for example, laser processing or machining.

Next, the conductive film 104 is formed on the inner wall of each hole 102. The conductive film 104 is formed by, for example, vapor phase or liquid phase deposition.

Next, the plurality of first plungers 110 and the first pin plate 130 are installed below the first elastomer 100, and the plurality of second plungers 120 and the second pin plate 140 are installed above the first elastomer 100.

The inspection device 10 is manufactured in this way.

According to the present embodiment, as compared with a case in which the plunger is biased by a spring, the first elastomer 100 plays a role of compression and extension of the spring, and the conductive film 104 plays a role of conduction of the spring. If the plunger is biased by the spring, a free length of the spring needs to be short to compare the free lengths of the probe. In this case, however, it is difficult to achieve a sufficient stroke. On the other hand, in the present embodiment, there is no need to use the spring. Accordingly, as compared with a case in which the plunger is biased by the spring, a natural length of the probe can be shortened while achieving the stroke having a sufficient length.

It should be noted that, in the present embodiment, the case has been described in which the first plunger 110 and the second plunger 120 overlap with the first elastomer 100 in the vertical direction Z. However, the first elastomer 100 and the second plunger 120 may overlap with the first elastomer 100 in a direction different from the vertical direction Z.

### Modification Example

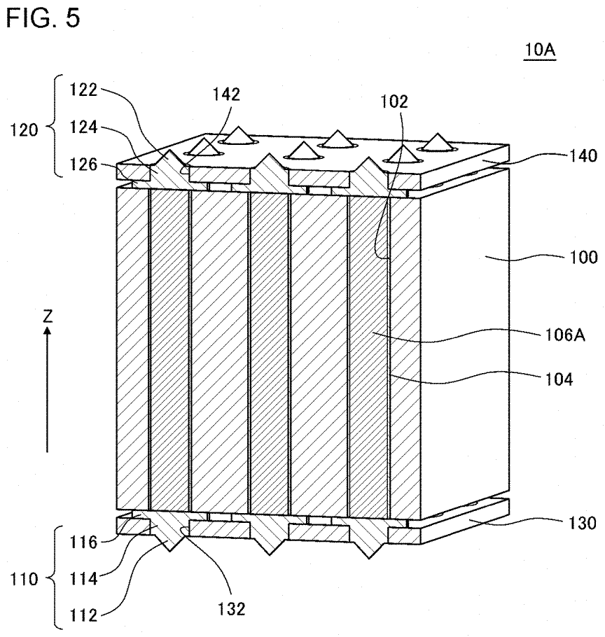

FIG. 5 is a perspective cross-sectional view of an inspection device 10A according to a modification example. The inspection device 10A according to the modification example is the same as the inspection device 10 according to Embodiment 1, except for the following points.

The hole 102 is solid with a second elastomer 106A. Accordingly, the first plunger 110 and the second plunger 120 can be biased not only by the first elastomer 100 but also by the second elastomer 106A. As a result, the elastic force received by the first plunger 110 and the second plunger 120 can be increased as compared with a case in which the second elastomer 106A is not provided. Further, peeling of the conductive film 104 can be suppressed as compared with a case in which the hole 102 is hollow.

A material for forming the second elastomer 106A may be the same as or different from the material for forming the first elastomer 100. For example, in the viewpoint of increasing the elastic modulus between the first plunger 110 and the second plunger 120, the elastic modulus of the material for forming the second elastomer 106A may be a relatively high elastic modulus, for example, may be an elastic modulus higher than the elastic modulus of the material for forming the first elastomer 100. From the viewpoint of suppressing peeling of the conductive film 104, the elastic modulus of the material for forming the second elastomer 106A may be a relatively low elastic modulus, for example, an elastic modulus lower than the elastic modulus of the material for forming the first elastomer 100.

### Embodiment 2

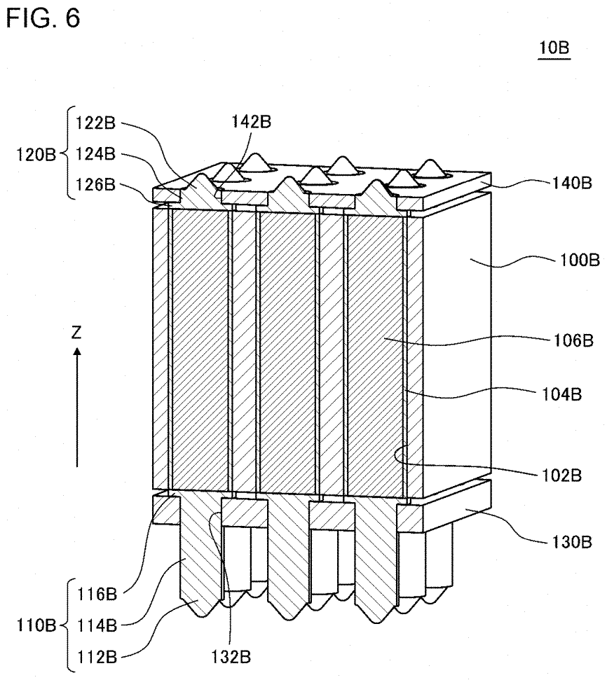

FIG. 6 is a perspective cross-sectional view of an inspection device 10B according to Embodiment 2. The inspection device 10B according to the embodiment is the same as the inspection device 10 according to Embodiment 1, except for the following points.

The inspection device 10B includes a socket 100B, a plurality of first plungers 110B, a plurality of second plungers 120B, a first pin plate 130B, and a second pin plate 140B. Each first plunger 110B includes a first tip contactor 112B, a first columnar part 114B, and a first receiving part 116B. Each second plunger 120B includes a second tip contactor 122B, a second columnar part 124B, and a second receiving part 126B.

The socket 100B is made of, for example, glass, ceramics, or organic resin.

The socket 100B defines a plurality of holes 102B that penetrate the socket 100B along the vertical direction Z.

A conductive film 104B is formed on an inner wall of the hole 102B. The conductive film 104B according to Embodiment 2 includes, for example, the same material as the material described for the conductive film 104 according to Embodiment 1.

The hole 102B is solid with a second elastomer 106B. The second elastomer 106B according to Embodiment 2 includes, for example, the same material as the material described for the second elastomer 106A according to the modification example.

The first plunger 110B is located below the socket 100B. The first plunger 110B overlaps with the hole 102B in the vertical direction Z. Accordingly, the first plunger 110B can be biased in a direction away from the second plunger 120B, that is, downward by the second elastomer 106B. The first plunger 110B is electrically connected to the conductive film 104B. Accordingly, the first plunger 110B can be electrically connected to the second plunger 120B through the conductive film 104B.

The first pin plate 130B defines a plurality of first through-holes 132B. In the same manner as the plurality of first plungers 110 and the first pin plate 130 according to Embodiment 1, each of the plurality of first plungers 110B is inserted into each of the plurality of first through-holes 132B.

The second plunger 120B is located above the socket 100B. The second plunger 120B overlaps with the hole 102B in the vertical direction Z. Accordingly, the second plunger 120B can be biased in a direction away from the first plunger 110B, that is, upward by the second elastomer 106B. The second plunger 120B is electrically connected to the conductive film 104B. Accordingly, the second plunger 120B can be electrically connected to the first plunger 110B through the conductive film 104B.

The second pin plate 140B defines a plurality of second through-holes 142B. In the same manner as the plurality of second plungers 120 and the second pin plate 140 according to Embodiment 1, each of the plurality of second plungers 120B is inserted into each of the plurality of second through-holes 142B.

It should be noted that, in the present embodiment, the first columnar part 114B is longer than the second columnar part 124B. However, the first columnar part 114B may be equal to the second columnar part 124B or may be shorter than the second columnar part 124B. In the present embodiment, the first pin plate 130B and the second pin plate 140B can be separated from the socket 100B. However, the inspection device 10 may not include at least one of the first pin plate 130B and the second pin plate 140B. When the inspection device 10 does not include the first pin plate 130B, the first receiving part 116B may be disposed to overlap with the hole 102B of the socket 100B in the vertical direction Z. In the same manner, when the inspection device 10 does not include the second pin plate 140B, the second receiving part 126B may be disposed to overlap with the hole 102B of the socket 100B in the vertical direction Z.

Also in Embodiment 2, as compared with a case in which the plunger is biased by the spring, the natural length of the probe can be shortened while achieving the stroke having a sufficient length.

In the above, the embodiments of the present invention have been described with reference to the drawings, but these are examples of the present invention, and various configurations other than the above can be adopted.

According to the present specification, the following aspects are provided.

(Aspect 1-1)

Aspect 1-1 is an inspection device including a first elastomer defining a hole, and a plunger overlapping with the first elastomer, in which a conductive film is formed over an inner wall of the hole, and the plunger is electrically connected to the conductive film.

According to Aspect 1-1, as compared with a case in which the plunger is biased by the spring, the first elastomer plays a role of compression and extension of the spring, and the conductive film plays a role of conduction of the spring. At least a portion of the first elastomer such as periphery of the hole, the conductive film, and the plunger function as the probe. If the plunger is biased by the spring, the free length of the spring needs to be short to compare the free lengths of the probe. In this case, however, it is difficult to achieve a sufficient stroke. On the other hand, in Aspect 1-1, there is no need to use the spring. Accordingly, as compared with a case in which the plunger is biased by the spring, a natural length of the probe can be shortened while achieving the stroke having a sufficient length.

(Aspect 1-2)

Aspect 1-2 is the inspection device according to Aspect 1-1, in which the plunger overlaps with the hole.

According to Aspect 1-2, the plunger can be directly connected to the conductive film without through the electrical path such as the conductive material embedded in the first elastomer that is separate from the conductive film. Accordingly, as compared with a case in which the electrical path is provided, the material and the process for manufacturing the electrical path are unnecessary, and the manufacturing cost of the inspection device can be reduced.

(Aspect 1-3)

Aspect 1-3 is the inspection device according to Aspect 1-1 or 1-2, in which the hole is hollow.

According to Aspect 1-2, as compared with a case in which the conductive film is formed on the inner wall of the hole and the hole is solid, the material and the process for making the hole solid are unnecessary, and the manufacturing cost of the inspection device can be reduced.

(Aspect 1-4)

Aspect 1-4 is the inspection device according to Aspect 1-1 or 1-2, in which the hole is solid with a second elastomer.

According to Aspect 1-4, the plunger can be biased not only by the first elastomer but also by the second elastomer. As a result, the elastic force received by the plunger can be increased as compared with a case in which the second elastomer is not provided. Further, peeling of the conductive film can be suppressed as compared with a case in which the hole is hollow.

(Aspect 1-5)

Aspect 1-5 is the inspection device according to any one of Aspects 1-1 to 1-4, further including a frame defining an opening, in which the first elastomer is provided in the opening of the frame.

According to Aspect 1-5, the first elastomer is supported by the inner edge of the opening. In this case, for example, even if the force is applied to the first plunger in the depth direction of the opening when the inspection device performs the inspection, spreading of the first elastomer in the planar direction perpendicular to the depth direction of the opening can be suppressed as compared with a case in which the first elastomer is not supported by the inner edge of the opening.

(Aspect 1-6)

Aspect 1-6 is the inspection device according to Aspect 1-5, in which the first elastomer has a portion embedded in the opening of the frame and a portion exposed from an opening end of the opening of the frame, and a width of the portion of the first elastomer exposed from the opening end of the opening is wider than a width of the opening end of the opening.

According to Aspect 1-6, the portion of the first elastomer exposed from the opening end of the opening can be suppressed from exiting to a side of the frame opposite to the opening end through the opening.

(Aspect 2-1)

Aspect 2-1 is a contactor including a socket defining a hole, and a plunger overlapping with the socket, in which a conductive film is formed over an inner wall of the hole, the plunger is electrically connected to the conductive film, and the hole is solid with an elastomer.

According to Aspect 2-1, as compared with a case in which the plunger is biased by the spring, the elastomer plays a role of compression and extension of the spring, and the conductive film plays a role of conduction of the spring. The conductive film, the elastomer, and the plunger function as the probe. If the plunger is biased by the spring, the free length of the spring needs to be short to compare the free lengths of the probe. In this case, however, it is difficult to achieve a sufficient stroke. On the other hand, in Aspect 2-1, there is no need to use the spring. Accordingly, as compared with a case in which the plunger is biased by the spring, a natural length of the probe can be shortened while achieving the stroke having a sufficient length.

This application claims priority based on Japanese Patent Application No. 2020-106765 filed on Jun. 22, 2020, the entire disclosure of which is incorporated herein by reference.

### REFERENCE SIGNS LIST

10 inspection device
10A inspection device
10B inspection device
100 first elastomer
100B socket
102 hole
102B hole
104 conductive film
104B conductive film
106A second elastomer
106B second elastomer
110 first plunger
110B first plunger
112 first tip contactor
112B first tip contactor
114 first columnar part
114B first columnar part
116 first receiving part
116B first receiving part
120 second plunger
120B second plunger
122 second tip contactor
122B second tip contactor
124 second columnar part
124B second columnar part
126 second receiving part
126B second receiving part
130 first pin plate
130B first pin plate
132 first through-hole
132B first through-hole
140 second pin plate
140B second pin plate
142 second through-hole
142B second through-hole
150 frame
152 opening
510 lower die
512 first recess part
520 upper die
522 second recess part
Z vertical direction

1. An inspection device comprising:
a first elastomer defining a hole; and
a plunger overlapping with the first elastomer,
wherein
a conductive film is formed over an inner wall of the hole, and
the plunger is electrically connected to the conductive film.

2. The inspection device according to claim 1,
wherein the plunger overlaps with the hole.

3. The inspection device according to claim 1,
wherein the hole is hollow.

4. The inspection device according to claim 1,
wherein the hole is solid with a second elastomer.

5. The inspection device according to claim 1, further comprising:
a frame defining an opening,
wherein the first elastomer is provided in the opening of the frame.

6. The inspection device according to claim 5,
wherein the first elastomer has a portion embedded in the opening of the frame and a portion exposed from an opening end of the opening of the frame, and
a width of the portion of the first elastomer exposed from the opening end of the opening is wider than a width of the opening end of the opening.

7. The inspection device according to claim 2,
wherein the hole is hollow.

8. The inspection device according to claim 2,
wherein the hole is solid with a second elastomer.

9. The inspection device according to claim 2, further comprising:
a frame defining an opening,
wherein the first elastomer is provided in the opening of the frame.

10. The inspection device according to claim 3, further comprising:
a frame defining an opening,
wherein the first elastomer is provided in the opening of the frame.

11. The inspection device according to claim 4, further comprising:
a frame defining an opening,
wherein the first elastomer is provided in the opening of the frame.
